(19) United States
(12) Patent Application Publication
(10) Pub. No.: US 2006/0175533 A1
(43) Pub. Date: Aug. 10, 2006

(54) Transport mechanism for carrying reagent box

(75) Inventors: Encong Liu, Beijing (CN); Jinsheng Yu, Beijing (CN); Xiaodong Wu, Beijing (CN)

Correspondence Address: EDWARDS & ANGELL, LLP, P.O. BOX 55874, BOSTON, MA, 02205, US

(73) Assignee: Beijing Yuande Bio-Medical Engineering Co., Ltd., Beijing (CN)

(21) Appl. No.: 11/165,952

(22) Filed: Jun. 24, 2005

(30) Foreign Application Priority Data
Feb. 5, 2005 (CN) 200510007851.X

(51) Int. Cl. H01L 27/00

(52) U.S. Cl. 250/208.1

(57) ABSTRACT

The present invention discloses a transport mechanism comprising an upper supporting board, a lower supporting board and a long board, wherein a X-direction guide groove is provided on said lower supporting board, and a guide rail is provided on said upper supporting board, the guide rail slidably engaging with the guide groove for the upper supporting board's travelling along a X-direction; the upper supporting board is further provided with a sliding chute whose width is identical to the width of the long board; said long board can be slidably inserted into the sliding chute, acting as a sliding rail in the Y-direction of the upper supporting board. With such a design, the structure of the whole transport mechanism becomes simplified, and further, the precise positioning of the upper and lower supporting boards as well as detective accuracy of sample are improved. Moreover, both driving motor and other related electrical components are fixed on a bracket instead of on the guide rail, thereby the weight of the moving parts being reduced and the movement of the electric wire being avoided. Therefore, the reliability of the machine is improved in its entirety.

### RELATED APPLICATIONS

This application claims priority to Chinese Application No. 200510007851.X, filed Feb. 5, 2005, the disclosure of which is incorporated herein in its entirety by this reference.

### TECHNICAL FIELD

The present invention relates to a transport mechanism for carrying reagent box in the medical detection device, wherein a long board and a Y-direction guide rail are the same one piece, that is, the long board acts as the Y-direction guide, and vice versa.

### BACKGROUND OF THE INVENTION

At present, “single photon counting instrument of micropore board” generally comprises a detector head, a reagent box, a transport mechanism for carrying the reagent box, a case, a control system and a computer, and so on. The detection procedure of “single photon counting instrument of micro-pore board” is shown as follows: according to the specified procedure, operator puts samples to be detected and corresponding reagent into corresponding holes in the micropore board and then makes some treatments; the treated micropore board is put on the horizontal tray in the counting instrument and the gate is closed; carried by the transport mechanism, the horizontal tray enters into the case; a lighting head of the detecting mechanism is aligned with the holes to be detected sequently through the travel of transport mechanism and detects the feeble fluorescence produced from the hole; finally, operator opens the gate and takes out the micropore board after completing the detection.

Because the detection object of “semiautomatic single photon counting instrument of micropore board” is feeble fluorescence, if a little light outside of the hole to be detected leaks to the detection position, the result will be affected. So the requirements for the light seal and positioning accuracy of motion parts are very strict. However, in the conventional transport mechanism, carried by driving mechanism, the upper and lower supporting boards travel along two guide rails of X-direction and Y-direction. (the detector head travels along Y-direction in some cases). The detector head fixed in the counting instrument detects each hole through the movement of the upper and lower supporting board. The associated electrical components move with the transport mechanism. In this case, the moving positioning accuracy is limited, thereby detective accuracy is affected. Furthermore, this results in complicated equipment structure and high manufacture costs.

### SUMMARY OF THE INVENTION

The object of the present invention is to overcome the drawbacks of a conventional transport mechanism and thereby to provide a transport mechanism having a long board and a Y-direction guide rail, wherein the long board and the Y-direction guide rail are the same one piece. In the transport mechanism, the long board which drives the upper supporting board to travel along X-direction also functions as the Y-direction guide rail, thereby a separate Y-direction guide rail is not needed. At the same time, both driving motor and other related electrical components are fixed on a bracket instead of on the guide rail, thereby the weight of the moving parts being reduced and the movement of the electric wire being avoided. Therefore, the reliability of the machine is improved in its entirety. With such a design, the structure of the whole transport mechanism becomes simplified, and further, the precise positioning of the upper and lower supporting boards as well as detective accuracy of sample are improved.

According to the present invention, a transport mechanism includes an upper supporting board, a lower supporting board and a long board, wherein said lower supporting board is provided with a X-direction guide groove, and a guide rail is provided on said upper supporting board, the guide rail slidably engaging with the guide groove so that the upper supporting board can travels along X-direction. Further, a sliding chute whose width is identical to the width of the long board is provided on the upper supporting board. Said long board can be sildably inserted into the sliding chute, acting as a sliding rail in the Y-direction of the upper supporting board.

Said upper supporting board, said lower supporting board and said long board are formed of plastic materials.

The present invention also provides a single photon counting instrument of micropore board, which includes the transport mechanism according to the present invention.

### BRIEF DESCRIPTION OF THE DRAWINGS

FIG. 1 shows the transport mechanism with the long board and the Y-direction guide rail being the same one piece according to the present invention, in which Fig. (a) is a front view of the transport mechanism, and Fig. (b) is a sectional view of the transport mechanism;

FIG. 2 is a schematic diagram of the lower supporting board of the transport mechanism as shown in Fig. 1;

FIG. 3 is a schematic diagram of the upper supporting board of the transport mechanism as shown in FIG. 1;

FIG. 4 is a schematic diagram of the long board of the transport mechanism as shown in FIG. 1;

FIG. 5 is a perspective view of the lower supporting board of the transport mechanism as shown in FIG. 2;

FIG. 6 is a perspective view of the upper supporting board of the transport mechanism as shown in FIG. 3; and

FIG. 7 is a perspective view of the long board of the transport mechanism as shown in FIG. 4.

### DETAILED DESCRIPTION OF THE INVENTION

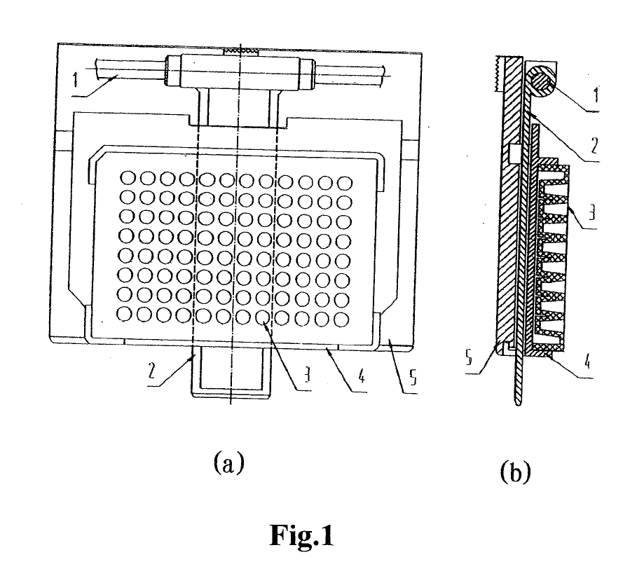

Now referring to the FIG. 1, the transport mechanism of the present invention includes a lower supporting board 5, an upper supporting board 4 and a long board 2. It should be understood that the complete transport mechanism also includes driving device such as driving motor, and connecting means, etc. But they are not shown in the figures because they belong to prior art. A reagent box 3 is provided on the upper supporting board 4.

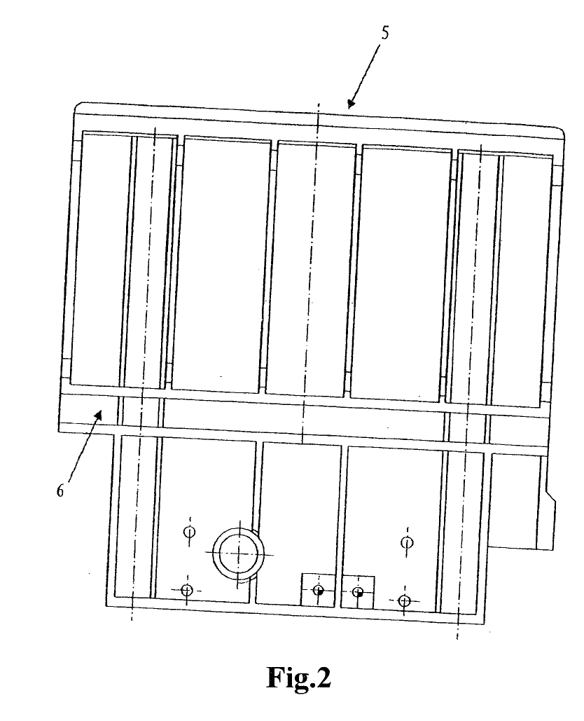

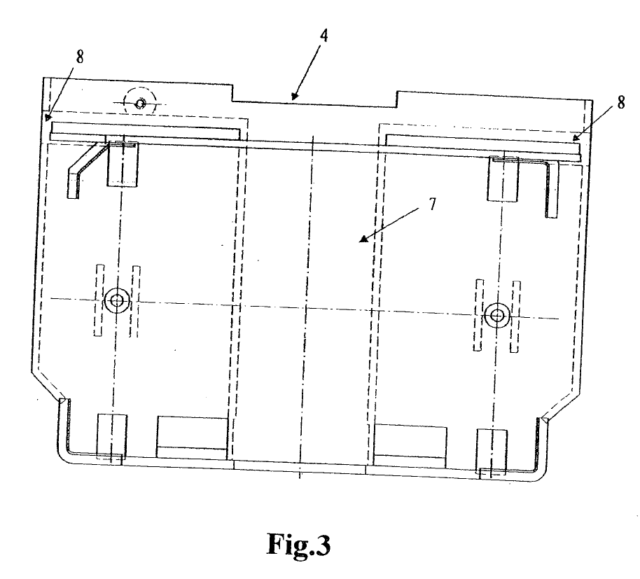

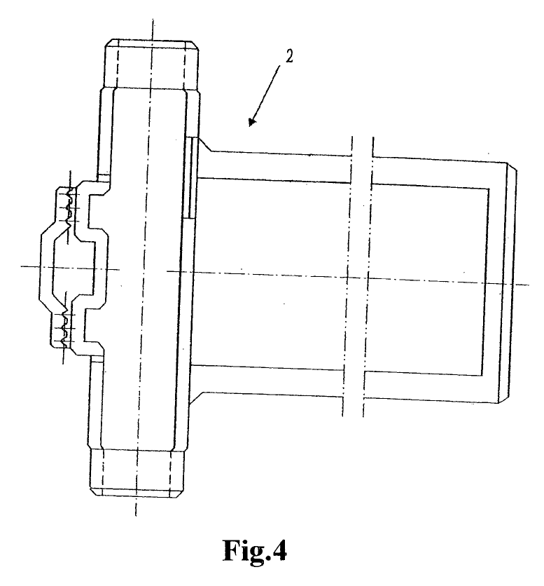

Referring to the FIG. 2, a X-direction guide groove 6 is provided on the lower supporting board 5. Correspondingly, a guide rail 8 is provided on the upper supporting board 4. Referring to the FIG. 3, the guide rail 8 slidably engages with the guide groove 6 so that the upper supporting board 4 can travel along the X-direction. A sliding chute 7 whose width is identical to the width of the long board 2 is provided on the upper supporting board 4. Referring to the FIG. 4, the long board 2 can be slidably inserted into the sliding chute 7.

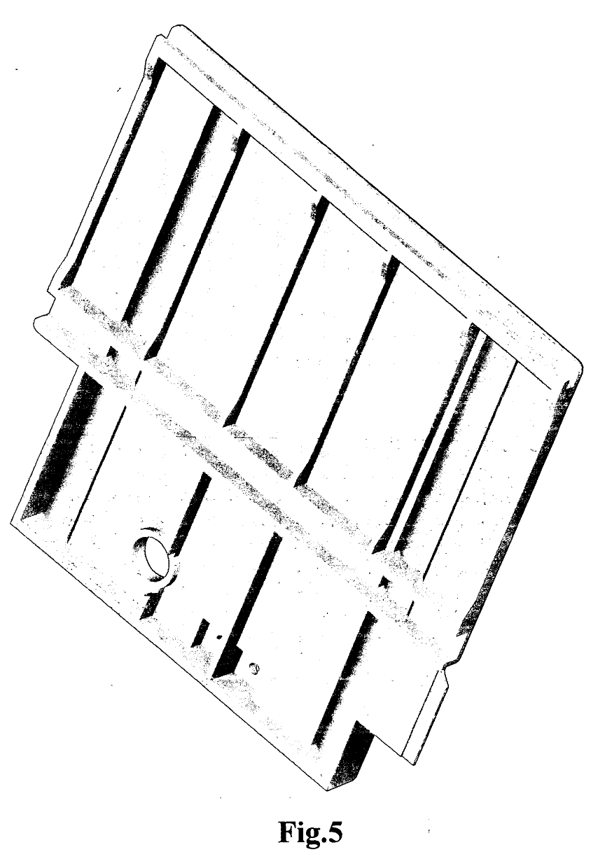

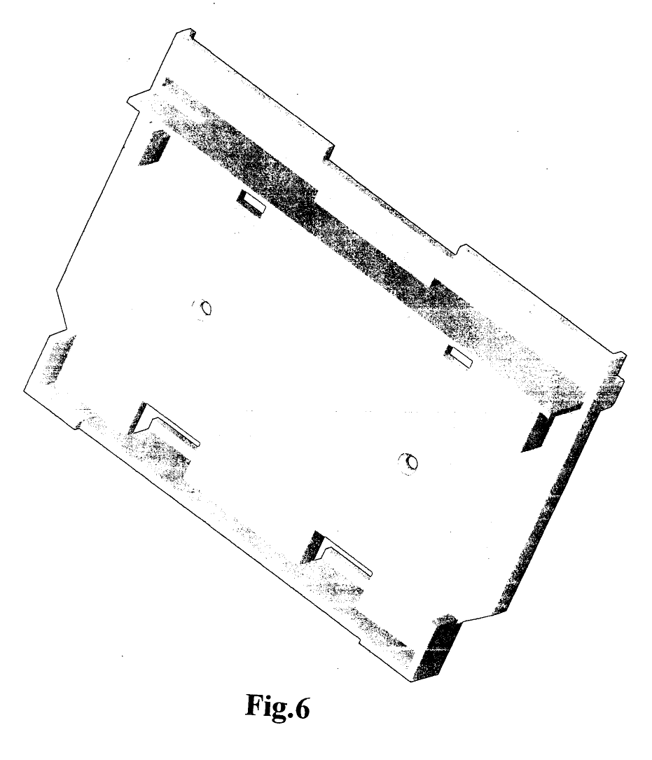

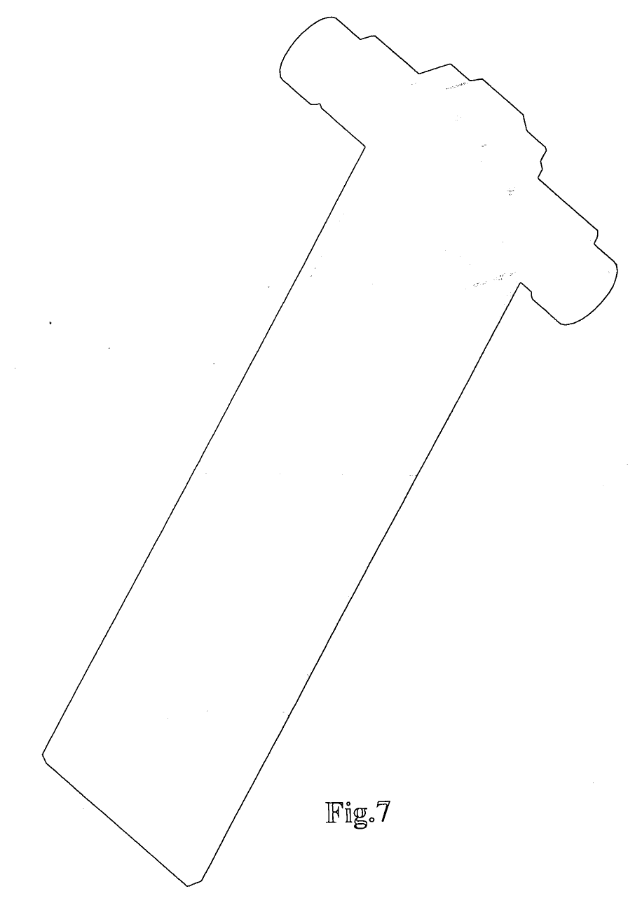

FIGS. 5-7 show the perspective views illustrating the lower support board, the upper supporting board and the long board of the transport mechanism according to the present invention, respectively.

Regarding the transport mechanism of the present invention, the reagent box 3 can travel in a two-dimensional plane, i.e., along a X-direction and a Y-direction, thereby completing the positioning with respect to the detector head. In the present invention, the X-direction is defined as a horizontal direction, and the Y-direction is defined as a vertical direction. The long board 2 drives the upper supporting board 4 by the guide rail 8 sliding in the X-direction guide groove 6 of the lower supporting board 5, thereby the movement in the X-direction is implemented. The lower supporting board 5 carries the upper supporting 4 to travel along the long board 2, thereby the movement in the Y-direction is implemented, in which the long board 2 is slidably inserted into the sliding chute 7 of the upper supporting board.

In the present invention, on the one hand, the long board 2 drives the upper supporting board 4 to travel in the X-direction, on the other hand, it is used as a Y-direction guide rail. So a separate Y-direction guide rail of the prior art is not needed. This structure makes the whole transport mechanism simplified and is beneficial to the traveling positioning of the reagent box 3.

In operation, the long board 2 travels along a plain shaft 1 in the X-direction (a driving mechanism is not shown) and carries the reagent box 3 to travel by means of the upper supporting board 4. The lower supporting board 5 carries the upper supporting 4 and the reagent box 3 to travel along the long board 2 in the Y-direction (a driving mechanism is not shown). The detector head detects the number of the photons in each sample after the reagent box 3 travels to a specified detecting position. The accuracy of traveling position is controlled by a numeral panel on a stepping motor. After the detection is completed, the lower supporting board 5 carries the upper supporting board 4 and the reagent box 3 to ram the gate open.

In an embodiment of the present invention, the whole transport mechanism, including the upper supporting board, the lower supporting board and the long board, may be formed of plastic materials. Therefore, the weight of the whole transport mechanism is reduced; the traveling speed is effectively improved; and running noises is depressed. In addition, the positioning accuracy in the X-direction depends on the guide rail on the plain shaft-long board-upper supporting board, and the positioning accuracy in the Y-direction depends on the guide rail between the upper supporting board and the lower supporting board. In this way, all of the parts are easy to manufacture and the precision thereof is easy to be controlled. Meanwhile, both driving motor and other related electrical components are fixed on a bracket instead of on the guide rail, thereby the weight of moving parts being reduced and the movement of the electric wire being avoided. So the reliability of the whole machine is improved.

The present invention also relates to a “single photon counting instrument of micropore board”, which includes the above-mentioned transport mechanism.

It should be understood, this invention may be implemented with many changes without departing from the spirit or essential characteristics thereof. The present embodiments are therefore not restrictive to any details in the above-mentioned embodiment. Therefore, unless the specific indication is made, the present invention should be explained extensively within the spirit and the scope as defined by the appended claims, and all changes that fall within metes and bounds of the claims, or equivalents of such metes and bounds are intended to be embraced by the claims.

Incorporation by Reference

The contents of all references, patents, pending patent applications and published patents, cited throughout this application are hereby expressly incorporated by reference.

Equivalents

Those skilled in the art will recognize, or be able to ascertain using no more than routine experimentation, many equivalents to the specific embodiments of the invention described herein. Such equivalents are intended to be encompassed by the following claims.

What is claimed is:

1. A transport mechanism, comprising an upper supporting board, a lower supporting board and a long board, characterized in that: a X-direction guide groove is provided on said lower supporting board, and a guide rail is provided on said upper supporting board, the guide rail slidably engaging with the guide groove for the upper supporting board's traveling along a X-direction; the upper supporting board is further provided with a sliding chute whose width is identical to the width of the long board; said long board can be slidably inserted into the sliding chute, acting as a sliding rail in the Y-direction of the upper supporting board.

2. The transport mechanism according to claim 1, characterized in that: said upper supporting board, said lower supporting board and said long board are all formed of plastic materials.

3. A single photon counting instrument of micropore board, including said transport mechanism according to claims 1 or 2.
